(19) United States
(12) Patent Application Publication
(10) Pub. No.: US 2006/0208365 A1
(43) Pub. Date: Sep. 21, 2006

(54) Flip-chip-on-film package structure

(75) Inventors: Geng-Shin Shen, Tainan City (TW); Tsai Kun Hsien, Hsinchu City (TW)

Correspondence Address: THE LAW OFFICES OF ANDREW D. FORTNEY, PH.D., P.C., 401 W FALLBROOK AVE STE 204, FRESNO, CA, 93711-5835, US

(73) Assignees: ChipMos Technologies Inc.; ChipMos Technologies (Bermuda) LTD.

(21) Appl. No.: 11/202,820

(22) Filed: Aug. 12, 2005

(30) Foreign Application Priority Data
Mar. 17, 2005 (TW) 094108261
May 25, 2005 (TW) 094117086

(51) Int. Cl. H01L 23/48

(52) U.S. Cl. 257/778

(57) ABSTRACT

A flip-chip-on-film package structure includes a flexible substrate, a flip chip, and a first heat sink. The flexible substrate has an upper surface and a lower surface. The flip chip is mounted on the upper surface of the flexible substrate and electrically connected to the flexible substrate. The first heat sink is disposed on the lower surface of the flexible substrate and used for dissipating the heat generated by the flip chip during operation. Moreover, the first heat sink can also improve the strength of the package structure.

### BACKGROUND OF THE INVENTION

1. Field of the invention

The invention relates to a flip-chip-on-film package structure, and more particularly to a flip-chip-on-film package structure capable of effectively dissipating the heat generated by the flip chip during operation.

2. Description of the prior art

In electronic industry of nowadays, a flip chip with high efficiency is mounted on a flexible substrate to package the chip on film. The flip-chip-on-film package structure can be applied to the electronic product with small size and light weight, such as integrated circuit (IC) chip. However, when the electronic product is working, the chip will generate heat and the heat cannot be always dissipated effectively. Furthermore, when the chip is being packaged and used, the chip may be damaged since the flexible substrate may be bended due to bad strength of the package structure. Then, the life of the electronic product will be shortened.

Referring to FIG. 1, FIG. 1 is a schematic diagram illustrating a flip-chip-on-film package structure 10 of the prior art. The flip-chip-on-film package structure 10 includes a flexible substrate 12, a flip chip 14, and a sealant 16. The flexible substrate 12 has an upper surface 120 and a lead layer 122 formed on the upper surface 120. The flip chip 14 has an active surface 140 and a back surface 142. At least one bump 144 is formed on the active surface 140 of the flip chip 14. When the flip chip 14 is mounted onto the flexible substrate 12, the bumps are electrically connected to the lead layer 122 of the flexible substrate 12. The sealant 16 is coated between the flip chip 14 and the flexible substrate 12.

In the aforementioned flip-chip-on-film package structure 10, the flip chip 14 will generate heat during operation, and the heat can only be dissipated by the back surface 142 of the flip chip 14. Furthermore, whenever the strength of the flexible substrate 12 is not enough to support the flip chip 14 thereon, the flip chip may be damaged as being packaged or used.

Therefore, the main objective of the invention is to provide a flip-chip-on-film package structure to solve the aforementioned problems.

### SUMMARY OF THE INVENTION

An objective of the invention is to provide a flip-chip-on-film package structure, wherein a heat sink is disposed on the lower surface of the flexible substrate for dissipating the heat generated by the flip chip during operation.

Another objective of the invention is to provide a flip-chip-on-film package structure, wherein a heat sink is disposed on the lower surface of the flexible substrate for improving the strength of the package structure.

According to a preferred embodiment of the invention, a flip-chip-on-film package structure includes a flexible substrate, a flip chip, and a first heat sink. The flexible substrate has an upper surface and a lower surface. The flip chip is mounted on the upper surface of the flexible substrate and electrically connected to the flexible substrate. The first heat sink is disposed on the lower surface of the flexible substrate and used for dissipating the heat generated by the flip chip during operation. Furthermore, the first heat sink can also improve the strength of the package structure.

Accordingly, the flip-chip-on-film package structure of the invention can not only effectively dissipate the heat generated by the flip chip during operation but also improve the strength of the package structure.

The advantage and spirit of the invention may be understood by the following recitations together with the appended drawings.

### BRIEF DESCRIPTION OF THE APPENDED DRAWINGS

FIG. 1 is a schematic diagram illustrating a flip-chip-on-film package structure of the prior art.

FIG. 2 is a schematic diagram illustrating a flip-chip-on-film package structure according to a first preferred embodiment of the invention.

FIG. 3 is a top view illustrating a flip-chip-on-film package structure according to a second preferred embodiment of the invention.

FIG. 4 is a sectional view along line X-X illustrating a flip-chip-on-film package structure shown in FIG. 3.

FIG. 5 is a schematic diagram illustrating a flip-chip-on-film package structure according to a third preferred embodiment of the invention.

FIG. 6 is a schematic diagram illustrating a flip-chip-on-film package structure according to a fourth preferred embodiment of the invention.

FIG. 7 is a schematic diagram illustrating a flip-chip-on-film package structure according to a fifth preferred embodiment of the invention.

FIG. 8 is a top view illustrating a flip-chip-on-film package structure according to a sixth preferred embodiment of the invention.

FIG. 9 is a sectional view along line P-P illustrating a flip-chip-on-film package structure shown in FIG. 8. FIG. 10 is a schematic diagram illustrating a flip-chip-on-film package structure according to a seventh preferred embodiment of the invention.

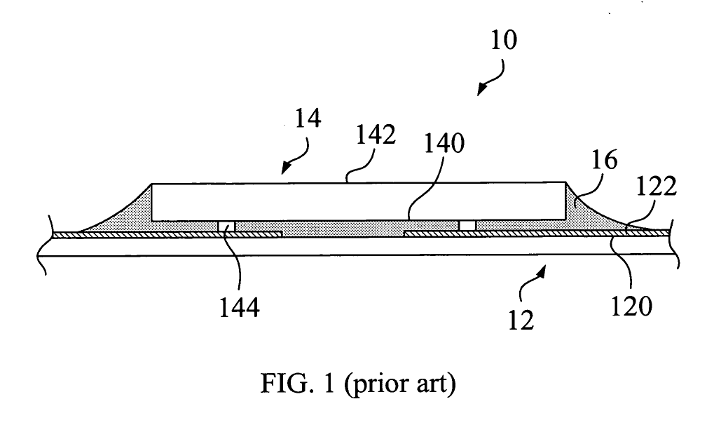

### DETAILED DESCRIPTION OF THE INVENTION

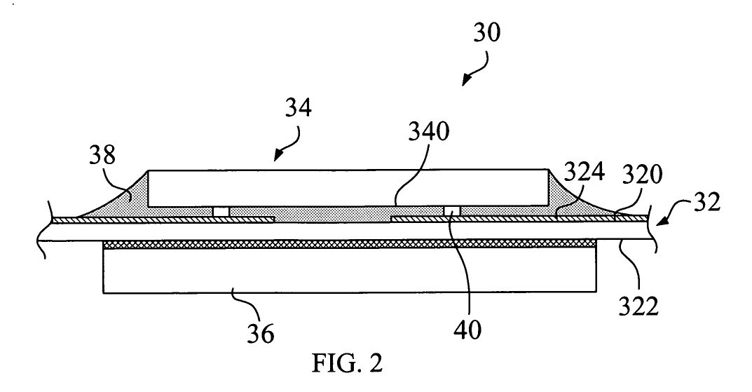

Referring to FIG. 2, FIG. 2 is a schematic diagram illustrating a flip-chip-on-film package structure 30 according to a first preferred embodiment of the invention. The flip-chip-on-film package structure 30 includes a flexible substrate 32, a flip chip 34, a first heat sink 36, and a sealant 38. The flexible substrate 32 can be a polyimide (PI) substrate or the like. The flexible substrate 32 has an upper surface 320, a lower surface 322, and a lead layer 324 formed on the upper surface 320. The flip chip 34 is mounted on the upper surface 320 of the flexible substrate 32 and has an active surface 340. At least one bump 40 is formed on the active surface 340 and electrically connected to the lead layer 324 of the flexible substrate 32. The sealant 38 is coated between the flip chip 34 and the flexible substrate 32, wherein the sealant 38 is one selected from the group consisting of an under-filling material, a resin, an anisotropic conductive paste (ACP) and an anisotropic conductive film (ACF).

As shown in FIG. 2, the first heat sink 36 is disposed on the lower surface 322 of the flexible substrate 32 and certainly located under the flip chip 34. The first heat sink 36 is used for dissipating the heat generated by the flip chip 34 during operation. The first heat sink 36 can be plastered on the lower surface 322 of the flexible substrate 32, wherein the material for plastering the first heat sink is one selected from the group consisting of a resin, a heat conductive paste, an anisotropic conductive paste (ACP), and an anisotropic conductive film (ACF). The first heat sink 36 can be also formed on the lower surface 322 of the flexible substrate 32 by a sputtering process, a coating process, or a sputtering plus electroplating process. In this embodiment, the size of the first heat sink is larger than the flip chip.

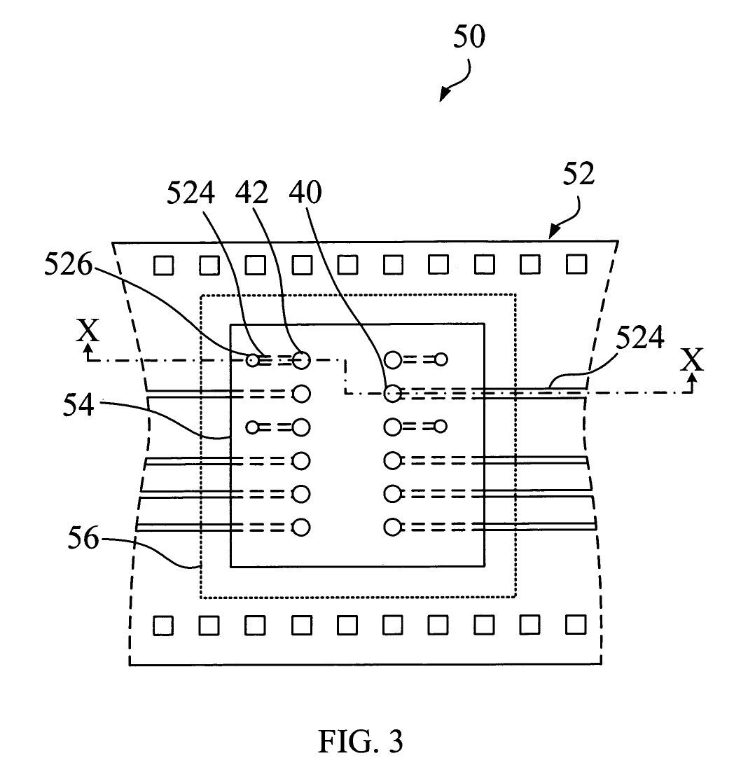

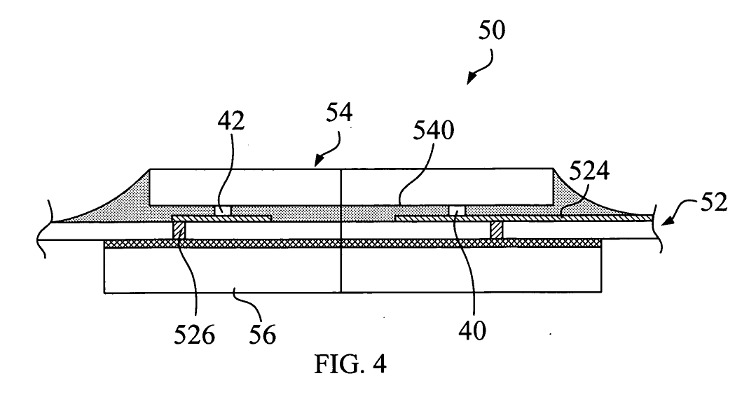

Referring to FIG. 3 and FIG. 4, FIG. 3 is a top view illustrating a flip-chip-on-film package structure 50 according to a second preferred embodiment of the invention. FIG. 4 is a sectional view along line X-X illustrating the flip-chip-on-film package structure 50 shown in FIG. 3. The main difference between the flip-chip-on-film package structure 50 and the flip-chip-on-film package structure 30 is that the flexible substrate 52 of the flip-chip-on-film package structure 50 further has at least one heat-conducting hole 526 and at least one dummy bump 42 formed on the active surface 540 of the flip chip 54, as shown in FIG. 4. In the flip-chip-on-film package structure 50, the dummy bumps 42 and the heat-conducting holes 526 are thermally coupled to the lead layer 524, such that the heat generated by the flip chip 54 during operation is conducted to the first heat sink 56 via the dummy bumps 42, the lead layer 524, and the heat-conducting holes 526, as shown in FIG. 3. Accordingly, the flip-chip-on-film package structure 50 can effectively dissipate the heat generated by the flip chip 54 during operation. The principle of the flip-chip-on-film package structure 50 shown in FIG. 3 is the same as the flip-chip-on-film package structure 30 shown in FIG. 2, and the related description is neglected.

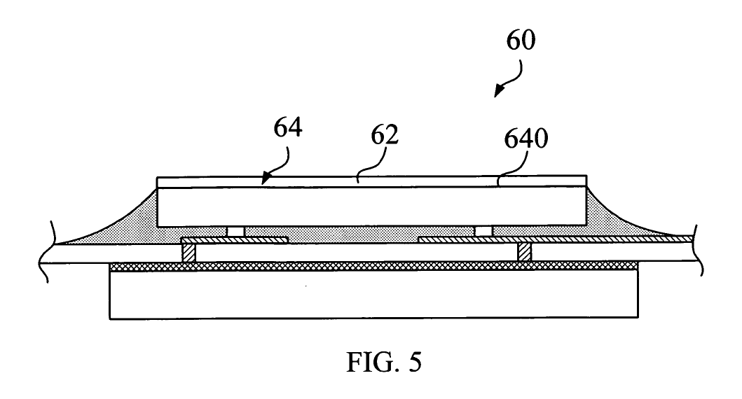

Referring to FIG. 5, FIG. 5 is a schematic diagram illustrating a flip-chip-on-film package structure 60 according to a third preferred embodiment of the invention. The main difference between the flip-chip-on-film package structure 60 and the flip-chip-on-film package structure 50 is that the flip-chip-on-film package structure 60 further includes a second heat sink 62, as shown in FIG. 5. In the flip-chip-on-film package structure 60, the second heat sink 62 is disposed on a back surface 640 of the flip chip 64 and used for dissipating the heat generated by the flip chip 64 during operation. The principle of the flip-chip-on-film package structure 60 shown in FIG. 5 is the same as the flip-chip-on-film package structure 50 shown in FIG. 3, and the related description is neglected.

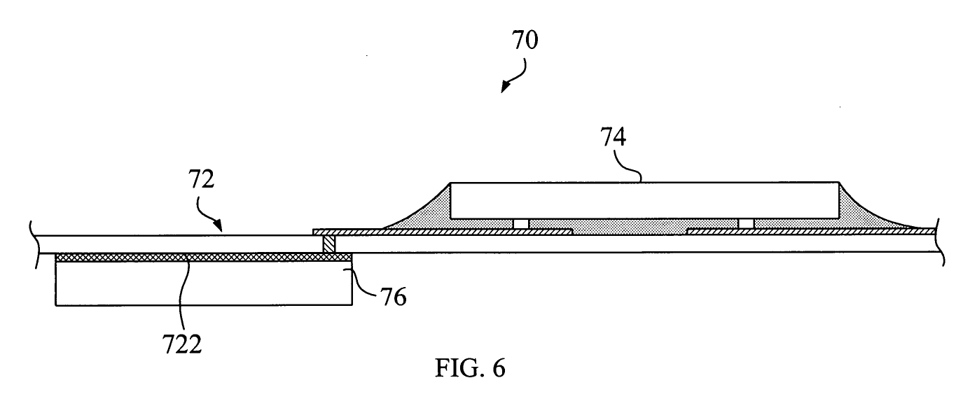

Referring to FIG. 6, FIG. 6 is a schematic diagram illustrating a flip-chip-on-film package structure 70 according to a fourth preferred embodiment of the invention. The main difference between the flip-chip-on-film package structure 70 and the flip-chip-on-film package structure 30 is that the first heat sink 76 of the flip-chip-on-film package structure 70 is disposed on the lower surface 722 of the flexible substrate 72 and located near the flip chip 74 for dissipating the heat generated by the flip chip 74 during operation. Accordingly, the flip-chip-on-film package structure can be designed based on various requirements. The principle of the flip-chip-on-film package structure 70 shown in FIG. 6 is the same as the flip-chip-on-film package structure 30 shown in FIG. 2, and the related description is neglected.

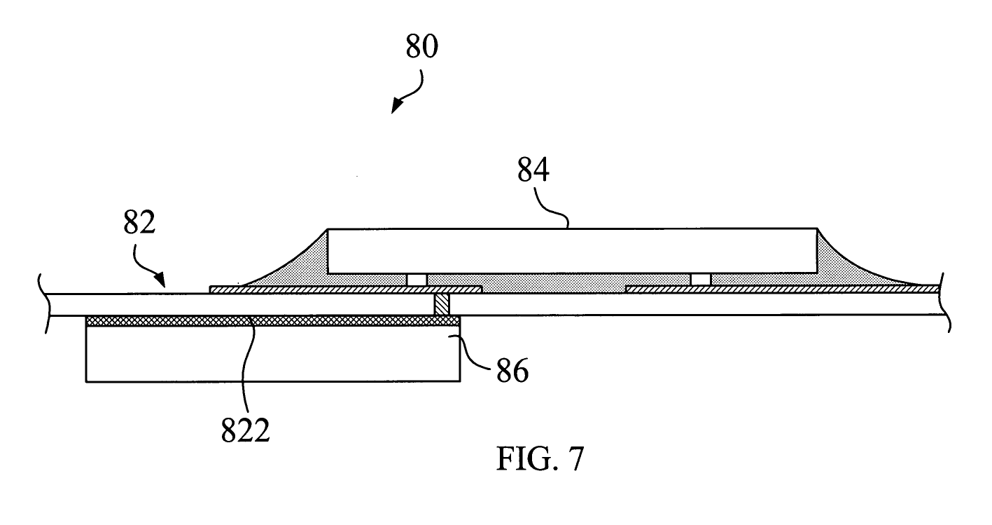

Referring to FIG. 7, FIG. 7 is a schematic diagram illustrating a flip-chip-on-film package structure 80 according to a fifth preferred embodiment of the invention. The main difference between the flip-chip-on-film package structure 80 and the flip-chip-on-film package structure 70 is that the first heat sink 86 of the flip-chip-on-film package structure 80 is disposed on the lower surface 822 of the flexible substrate 82, and a part of the first heat sink 86 overlaps with the flip chip 84. The first heat sink 86 is used for dissipating the heat generated by the flip chip 84 during operation. Accordingly, the flip-chip-on-film package structure can be designed based on various requirements. The principle of the flip-chip-on-film package structure 80 shown in FIG. 7 is the same as the flip-chip-on-film package structure 70 shown in FIG. 6, and the related description is neglected.

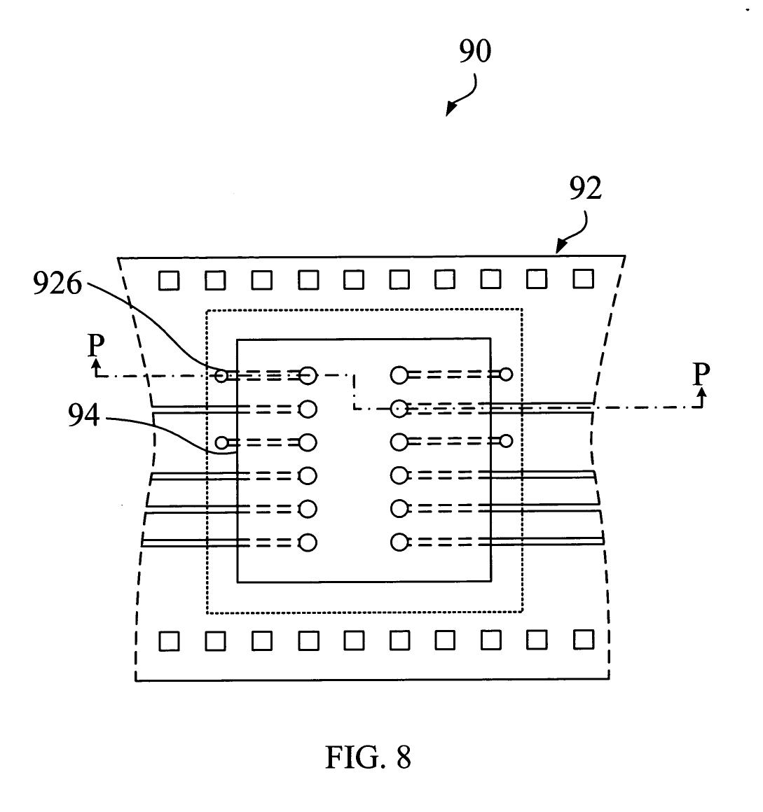

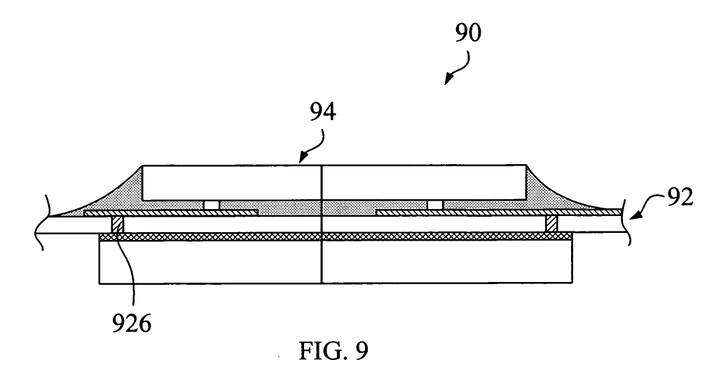

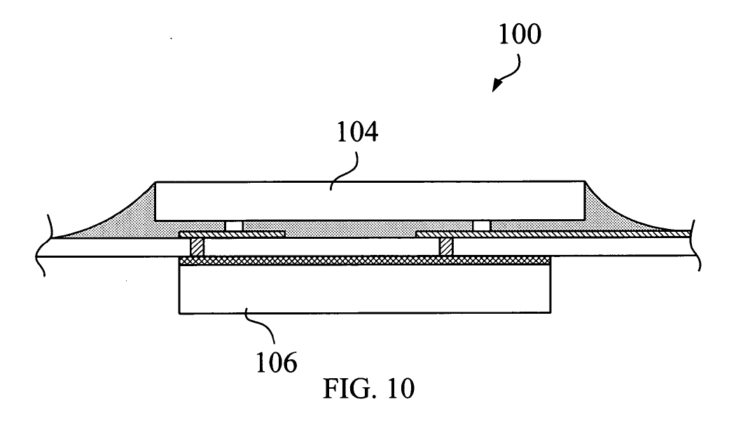

Referring to FIG. 8 and FIG. 9, FIG. 8 is a top view illustrating a flip-chip-on-film package structure 90 according to a sixth preferred embodiment of the invention. FIG. 9 is a sectional view along line P-P illustrating the flip-chip-on-film package structure 90 shown in FIG. 8. The main difference between the flip-chip-on-film package structure 90 and the flip-chip-on-film package structure 50 is that the heat-conducting hole 926 of the flexible substrate 92 of the flip-chip-on-film package structure 90 is formed away from the flip chip 94 instead of certainly under the flip chip 94, as shown in FIG. 8 and FIG. 9. The principle of the flip-chip-on-film package structure 90 shown in FIG. 8 is the same as the flip-chip-on-film package structure 50 shown in FIG. 3, and the related description is neglected.

Referring to FIG. 10, FIG. 10 is a schematic diagram illustrating a flip-chip-on-film package structure 100 according to a seventh preferred embodiment of the invention. The main difference between the flip-chip-on-film package structure 100 and the flip-chip-on-film package structure 50 is that the size of the first heat sink 106 of the flip-chip-on-film package structure 100 is smaller than the flip chip 104. Accordingly, the flip-chip-on-film package structure can be designed based on various requirements. The principle of the flip-chip-on-film package structure 100 shown in FIG. 10 is the same as the flip-chip-on-film package structure 50 shown in FIG. 3, and the related description is neglected.

Compared to the prior art, the flip-chip-on-film package structure of the invention can not only effectively dissipate the heat generated by the flip chip during operation but also improve the strength of the package structure.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A flip-chip-on-film package structure, comprising:
a flexible substrate having an upper surface and a lower surface;
a flip chip mounted on the upper surface of the flexible substrate and electrically connected to the flexible substrate; and
a first heat sink, disposed on the lower surface of the flexible substrate, for dissipating the heat generated by the flip chip during operation.

2. The flip-chip-on-film package structure of claim 1, further comprising a sealant coated between the flip chip and the flexible substrate.

3. The flip-chip-on-film package structure of claim 2, wherein the sealant is one selected from the group consisting of an under-filling material, a resin, an anisotropic conductive paste (ACP), and an anisotropic conductive film (ACF).

4. The flip-chip-on-film package structure of claim 1, wherein the flexible substrate further comprises a lead layer formed on the upper surface thereof and electrically connected to the flip chip.

5. The flip-chip-on-film package structure of claim 4, wherein the flip chip has an active surface, and at least one bump is formed on the active surface and electrically connected to the lead layer of the flexible substrate.

6. The flip-chip-on-film package structure of claim 4, wherein the flexible substrate also has at least one heat-conducting hole for conducting the heat generated by the flip chip during operation to the first heat sink.

7. The flip-chip-on-film package structure of claim 6, wherein the lead layer is thermally coupled to the at least one heat-conducting hole.

8. The flip-chip-on-film package structure of claim 7, wherein the flip chip has an active surface, and at least one dummy bump is formed on the active surface and thermally coupled to the lead layer, such that the heat generated by the flip chip during operation is conducted to the first heat sink via the at least one dummy bump, the lead layer and the at least one heat-conducting hole.

9. The flip-chip-on-film package structure of claim 1, wherein the first heat sink is plastered on the lower surface of the flexible substrate.

10. The flip-chip-on-film package structure of claim 9, wherein the material for plastering the first heat sink is one selected from the group consisting of a resin, a heat conductive paste, an anisotropic conductive paste (ACP), and an anisotropic conductive film (ACF).

11. The flip-chip-on-film package structure of claim 1, wherein the first heat sink is formed on the lower surface of the flexible substrate by a sputtering process.

12. The flip-chip-on-film package structure of claim 1, wherein the first heat sink is formed on the lower surface of the flexible substrate by a coating process.

13. The flip-chip-on-film package structure of claim 1, wherein the first heat sink is formed on the lower surface of the flexible substrate by a sputtering plus electroplating process.

14. The flip-chip-on-film package structure of claim 1, further comprising a second heat sink disposed on a back surface of the flip chip and used for dissipating the heat generated by the flip chip during operation.

15. The flip-chip-on-film package structure of claim 1, wherein the flexible substrate is a polyimide (PI) substrate.

16. The flip-chip-on-film package structure of claim 1, wherein the first heat sink is certainly located under the flip chip.

17. The flip-chip-on-film package structure of claim 1, wherein the first heat sink is located near the flip chip.

18. The flip-chip-on-film package structure of claim 17, wherein a part of the first heat sink overlaps with the flip chip.
